(19) United States
(12) Patent Application Publication
(10) Pub. No.: US 2026/0025927 A1
(43) Pub. Date: Jan. 22, 2026

(54) AUXILIARY PRODUCTION CLAMP FOR POWER MODULE AND USING METHOD THEREOF

(71) Applicant: Delta Electronics, Inc., Taoyuan City (TW)

(72) Inventors: Wenpei Shu, Shanghai (CN); Kun Jiang, Shanghai (CN)

(21) Appl. No.: 19/249,044

(22) Filed: Jun. 25, 2025

(30) Foreign Application Priority Data
Jul. 19, 2024 (CN) 202410976887.1

(51) Int. Cl. H05K 1/18; H01F 27/24; H05K 1/14

(52) U.S. Cl. CPC H05K 1/181; H01F 27/24; H05K 1/14; H05K 2201/1003

(57) ABSTRACT

An auxiliary production clamp including a first clamp element, a second clamp element, a pivot shaft, an elastic component and an ejector assembly for a power module and a using method thereof are disclosed. The second clamp element includes a through opening running through a second pressing end and spatially corresponding to a first pressing end of the first clamp element. The pivot shaft is pivotally connected between the first clamp element and the second clamp element. The elastic component is sleeved on the pivot shaft to provide a pressing force. The ejector assembly is provided on the second pressing end and spatially corresponding to the through opening. In a working state, the first pressing end presses against a upper first magnetic core of the power module, and an abutting end of the ejector assembly is driven to run through the through opening and push against the second magnetic core.

### CROSS-REFERENCE TO RELATED APPLICATION

This application claims priority to China Patent Application No. 202410976887.1, filed on Jul. 19, 2024. The entire contents of the above-mentioned patent application are incorporated herein by reference for all purposes.

### FIELD OF THE INVENTION

The present disclosure relates to a clamp used for an electronic component, and more particularly to an auxiliary production clamp for a power module and a using method thereof.

### BACKGROUND OF THE INVENTION

With the rapid development of artificial intelligence and data centers, DC (Direct Current) power modules have become an indispensable part of them. The DC power modules can provide higher energy efficiency, reduce energy loss, and play a key role in promoting sustainable energy development and intelligence. In the design of the DC power modules, the magnetic core is an important component in the power module, and mainly used to control the inductance and improve the conversion efficiency. The functions of the magnetic core include:

1. Controlling inductance: The magnetic core can be placed in the inductor. By managing the inductance path and guiding the magnetic flux, the size of the inductance and the inductive characteristics of the coil can be controlled. Voltage boost, voltage drop, filtering, current limiting and protection can all be achieved through the inductor.

2. Improving conversion efficiency: The magnetic core can convert the energy in the power module into the required output current or voltage, thereby improving the conversion efficiency. Different outputs can be achieved according to different designs and characteristics of the magnetic core.

3. Thermal conductivity of the core material: The thermal conductivity of the core material plays an important role in the heat dissipation and the stability of the power module.

Therefore, the assembling process of the magnetic core has become a critical step in the production of the DC power module. It is necessary to reduce the risks caused by manual operations and ensure the structural stability of the magnetic core after being assembled.

The main structure of a common DC power module is divided into two layers including an upper circuit-board assembly and a lower circuit-board assembly. The two circuit-board layers are welded together via conductive connectors. The upper circuit-board assembly includes an upper circuit board and a magnetic component. The magnetic component includes an upper magnetic core and a lower magnetic core, which are both fastened onto the upper circuit board through the through holes. The lower circuit-board assembly includes a lower circuit board. An opening is disposed on the lower circuit board spatially corresponding to the center position of the magnetic component.

The most common method of clamping the magnetic cores of the power module is to install a lower spring loaded pin on a metal base. First, one single module that has not been glued is placed on the metal base through the lower spring loaded pin. At this time, the lower spring loaded pin runs through the opening of the lower circuit board to push the lower magnetic core. The lower magnetic core is pressed and attached to the upper circuit board. Then, the glue dispensing operation is performed and the upper magnetic core is assembled. Thereafter, another metal base with an upper spring loaded pin is fastened on the foregoing metal base. The upper spring loaded pin is synchronously pressed onto the upper magnetic core until the upper magnetic core is fit with the upper circuit board. Since the upper spring pin is designed to have the elastic force greater than that of the lower spring pin, the lower magnetic core is spaced apart from the upper circuit board and a certain gap is formed. Finally, the entire module and the clamp are heated together. Although the clamp with the above structure design can effectively complete the assembly of the magnetic components in the module, the clamp structure and the manual operation are quite complicated. It causes the cost and efficiency problems to the large-scale production of DC power modules. This brings cost and efficiency problems for the large-scale production of DC power modules.

In view of this, there is a need of providing an auxiliary production clamp for a power module and a using method thereof, which includes a new design structure for solving the above-mentioned problems of the conventional clamp, so that the clamp structure is simplified and the production efficiency of the power module is improved at the same time.

### SUMMARY OF THE INVENTION

An object of the present disclosure is to provide an auxiliary production clamp for a power module and a using method thereof. After all components of a DC power module are assembled, it is necessary to ensure the uniformity of the glue between the upper magnetic core and the upper circuit board, and the glue between the upper magnetic core and the lower magnetic core. Moreover, before the glue is cured at high temperature, the structural stability of the magnetic cores after being assembled is also important. The present disclosure provides an ejector assembly assembled by utilizing high-temperature-resistant metal clips. In a working state, the effective pressing action of the upper magnetic core and the lower magnetic core in the power module can be completed simultaneously, and the operation is simple and fast. After the power module and the auxiliary production clamp are processed through the high-temperature furnace, the glue between the two magnetic cores and the glue between the upper magnetic core and the upper circuit board are completely cured, and then the auxiliary production clamp can be opened to remove the power module easily.

Another object of the present disclosure is to provide an auxiliary production clamp for a power module and a using method thereof. The main structure of the power module includes an upper circuit board, a lower circuit board, an upper magnetic core and a lower magnetic core. The lower magnetic core is disposed between the upper circuit board and the lower circuit board, and the upper magnetic core is disposed on the first surface of the upper circuit board. During the assembling and manufacturing of the magnetic component, the lower magnetic core is pre-placed on the second surface of the upper circuit board, and is attached to the second surface of the upper circuit board by the lower magnetic core's own gravity. Then, the third surface of the lower circuit board is placed horizontally to face downward on the second surface of the upper circuit board. After welding, the upper circuit board and the lower circuit board are connected together. Next, the power module is flipped horizontally so that the fourth surface of the lower circuit board faces downward. At this time, the lower magnetic core falls to the third surface under the action of its own gravity. After the glue is dispensed on the corresponding positions of the lower magnetic core and the upper circuit board, the upper magnetic core is further placed on the upper circuit board. In this way, the auxiliary production clamp is utilized to clamp the power module after being assembled. It ensures the uniformity of the glue between the upper magnetic core and the upper circuit board, and the glue between the upper magnetic core and the lower magnetic core. Furthermore, before the glue is cured at a high temperature, the structural stability of the magnetic cores after being assembled is maintained. When the assembled power module is clamped by the auxiliary production clamp, the ejector pin of the ejector assembly runs through the opening of the lower circuit board, and the pressing force of the upper clamp element on the upper magnetic core and the lower clamp element on the second circuit board is greater than the lifting force of the ejector assembly on the lower magnetic core, and the power module is clamped between the upper clamp element and the lower clamp element, while the structural stability of the magnetic component is maintained. After the power module and the auxiliary production clamp are processed through the high-temperature furnace, the glue is evenly cured to bond the magnetic component, and bond the upper magnetic core and the upper circuit board. Thereafter, the auxiliary production clamp can be removed easily to complete the manufacture of the power module.

In accordance with an aspect of the present disclosure, an auxiliary production clamp for a power module is provided and includes a first clamp element, a second clamp element, a pivot shaft, an elastic component and an ejector assembly. The first clamp element includes a first pressing end. The second clamp element includes a second pressing end and a through opening, wherein the through opening runs through the second pressing end, and the second pressing end is spatially corresponding to the first pressing end. The pivot shaft is pivotally connected between the first clamp element and the second clamp element to allow the first pressing end and the second pressing end to approach or separate from each other. The elastic component is sleeved on an outer periphery of the pivot shaft and abutted between the first clamp element and the second clamp element to provide a pressing force causing the first pressing end and the second pressing end close to each other. The ejector assembly is provided on the second pressing end and includes an ejector pin, a metal tube, an engagement component and a compression spring, wherein the ejector pin includes an abutting end, a clamped end and a limiting portion, the abutting end and the clamped end are two opposite ends of each other, the limiting portion is located between the abutting end and the clamped end, a top opening of the metal tube is aligned with the through opening of the second clamp element, and the metal tube and first clamp element are arranged on two opposite sides of the second clamp element, respectively, wherein the limiting portion of the ejector pin is accommodated in the metal tube, the clamped end runs through a bottom of the metal tube to engage with the engagement component, and the compression spring is accommodated in the metal tube and arranged between the limiting portion and the bottom of the metal tube, wherein when an external pressure is acted on the ejector pin, the limiting portion is slid along an interior of the metal tube to compress the compression spring, wherein when the external pressure is eliminated, an elastic force of the compression spring pushes the limiting portion to slide in an opposite direction along the metal tube until the engagement component abuts the bottom of the metal tube.

In accordance with another aspect of the present disclosure, a using method of an auxiliary production clamp for a power module is provided and includes a step of providing the auxiliary production clamp, wherein the auxiliary production clamp is operated in a working state to clamp a first magnetic core, a first circuit board, a second magnetic core and a second circuit board of the power module, wherein the first circuit board includes a first surface, a second surface and a through hole, and the through hole runs through the first surface and the second surface, wherein the first magnetic core and the second magnetic core are disposed on the first surface and the second surface, respectively, and buckled on the first circuit board through the through hole, wherein the second circuit board includes a third surface, a fourth surface, and a hollow opening, the third surface faces the second surface, the hollow opening runs through the third surface and the fourth surface and is disposed and spatially corresponding to the second magnetic core, and the second magnetic core is at least via exposed through the hollow opening, wherein the auxiliary production clamp includes a first clamp element, a second clamp element, a pivot shaft, an elastic component and an ejector assembly. The first clamp element includes a first pressing end. The second clamp element includes a second pressing end and a through opening, wherein the through opening runs through the second pressing end, and the second pressing end is spatially corresponding to the first pressing end. The pivot shaft is pivotally connected between the first clamp element and the second clamp element to allow the first pressing end and the second pressing end to approach or separate from each other. The elastic component is sleeved on an outer periphery of the pivot shaft and abutted between the first clamp element and the second clamp element to provide a pressing force causing the first pressing end and the second pressing end close to each other. The ejector assembly is provided on the second pressing end and spatially corresponding to the through opening and the hollow opening, wherein when the auxiliary production clamp is operated in the working state, the first pressing end presses against the first magnetic core, the second pressing end presses against the second circuit board, and the pressing force of the elastic component pushes against the ejector assembly, so that an abutting end of the ejector assembly is driven to run through the through opening of the second clamp element and the hollow opening of the second circuit board and push against the second magnetic core.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a structural perspective view illustrating an auxiliary production clamp and a power module according to an embodiment of the present disclosure;

FIG. 2A is a structural perspective view illustrating the power module according to the embodiment of the present disclosure;

FIG. 2B and FIG. 2C are exploded structural views illustrating the power module according to the embodiment of the present disclosure;

FIG. 3A is a structural perspective view illustrating the auxiliary production clamp according to the embodiment of the present disclosure;

FIG. 3B and FIG. 3C are exploded structural views illustrating the auxiliary production clamp according to the embodiment of the present disclosure;

FIGS. 4A to 4D are schematic diagrams illustrating a process of using the auxiliary production clamp to produce the power module according to an embodiment of the present disclosure;

FIG. 5 is a cross-sectional view illustrating the auxiliary production clamp operated in a working state to clamp the power module according to the embodiment of the present disclosure;

FIG. 6 is a cross-sectional view illustrating the auxiliary production clamp having the ejector assembly not affected by an external force according to the embodiment of the present disclosure; and

FIG. 7 is a cross-sectional view illustrating the auxiliary production clamp operated in an initial state according to the embodiment of the present disclosure.

### DETAILED DESCRIPTION

The present disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed. Further, spatially relative terms, such as “upper,” “lower,” “top,” “bottom,” “right,” “left” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second,” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items.

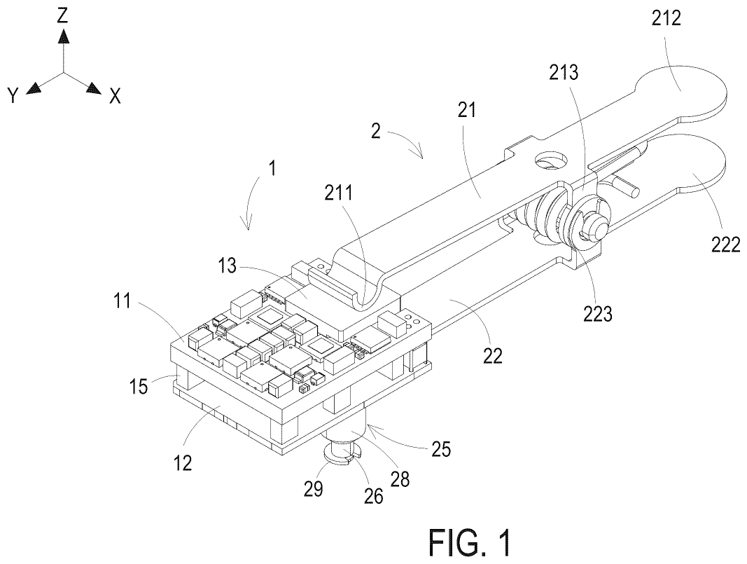

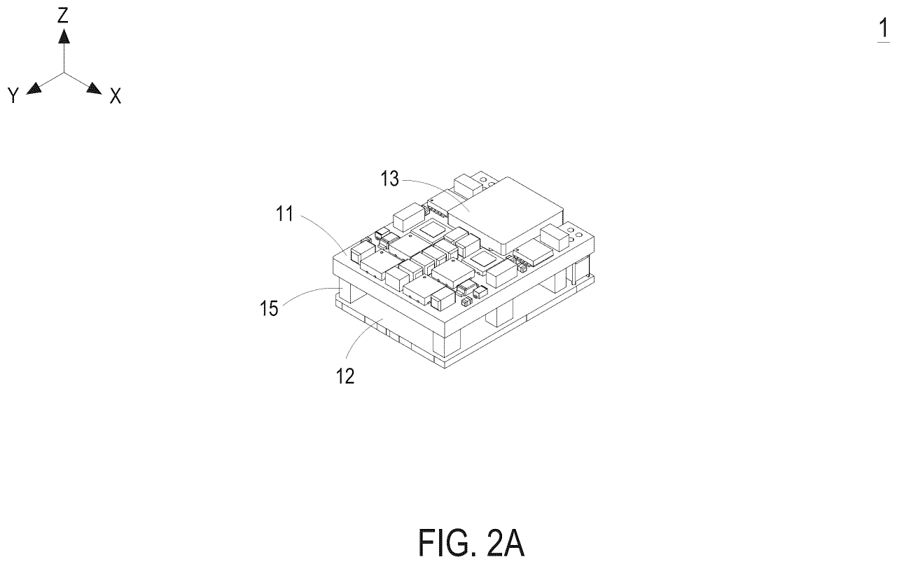

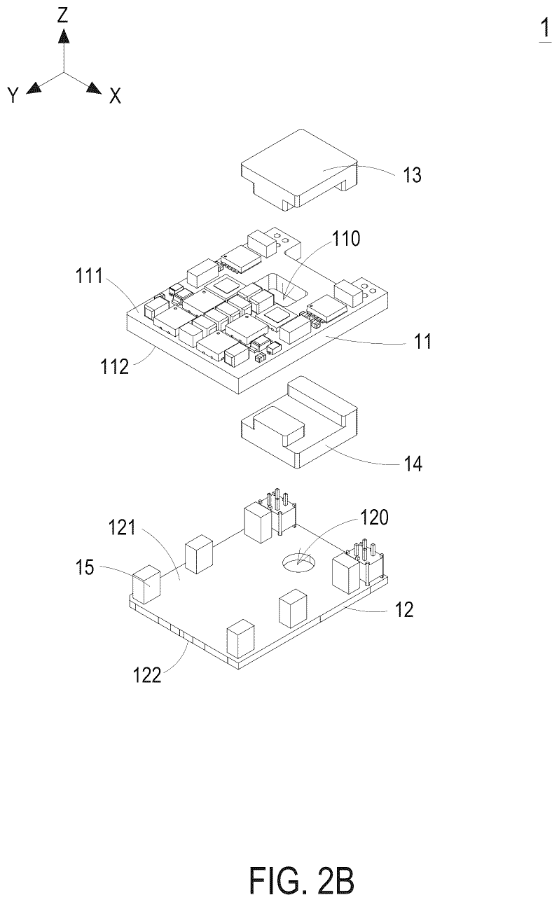

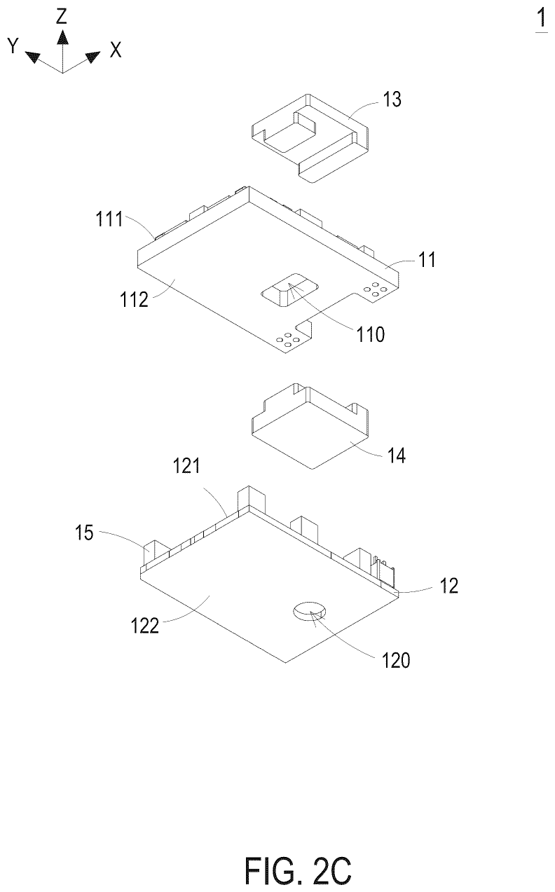

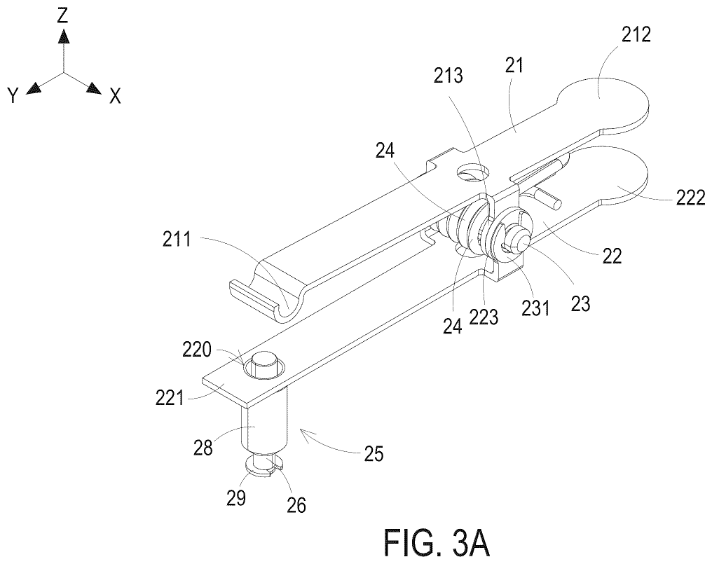

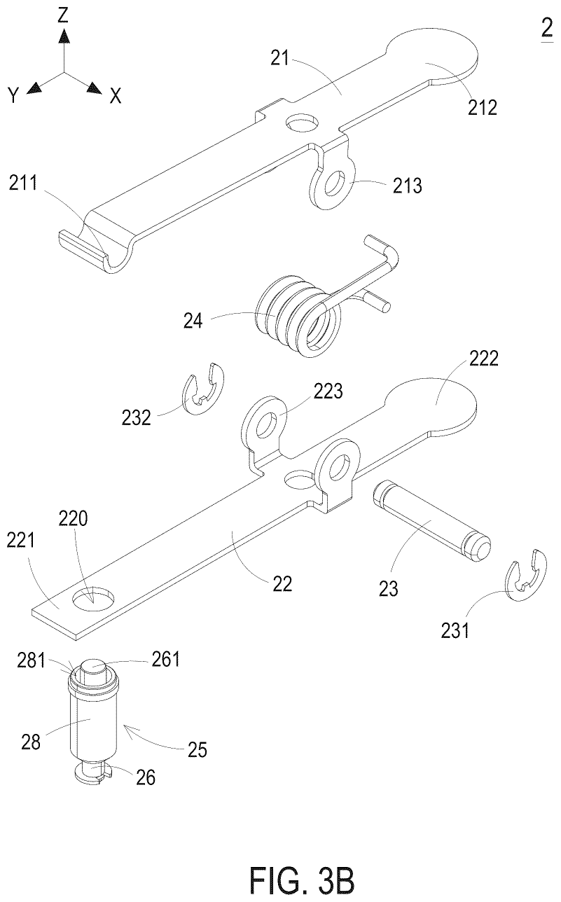

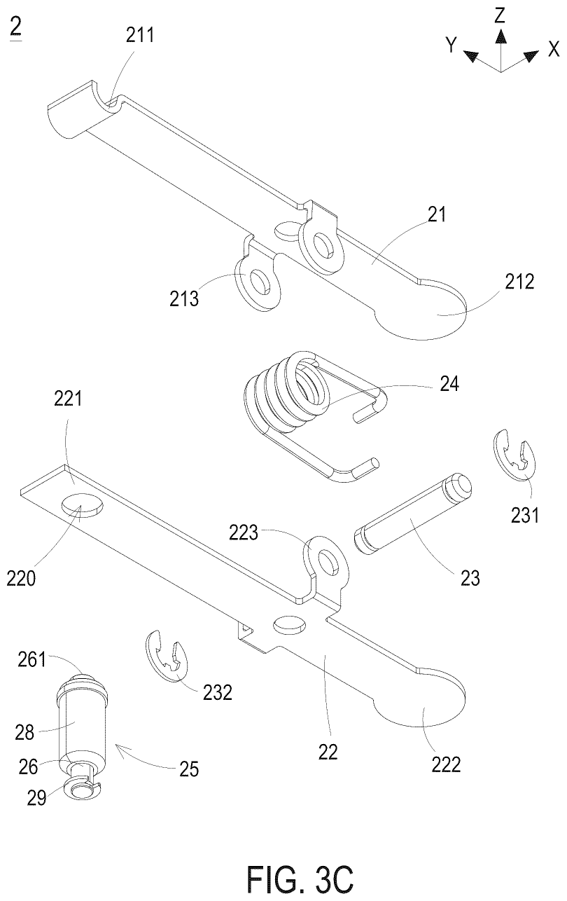

FIG. 1 is a structural perspective view illustrating an auxiliary production clamp and a power module according to an embodiment of the present disclosure. FIG. 2A is a structural perspective view illustrating the power module according to the embodiment of the present disclosure. FIG. 2B and FIG. 2C are exploded structural views illustrating the power module according to the embodiment of the present disclosure. FIG. 3A is a structural perspective view illustrating the auxiliary production clamp according to the embodiment of the present disclosure. FIG. 3B and FIG. 3C are exploded structural views illustrating the auxiliary production clamp according to the embodiment of the present disclosure. In the embodiment, the present disclosure provides an auxiliary production clamp 2, which is utilized to clamp an assembled structure of a power module 1, so as to maintain the structural stability of the power module 1 being assembled and complete the high-temperature curing process of a glue. The power module 1 includes a first circuit board 11, a magnetic component and a second circuit board 12. In some embodiments, the first circuit board 11 is an upper circuit board and includes a first surface 111, a second surface 112 and a through hole 110. The through hole 110 runs through the first surface 111 and the second surface 112. In some embodiments, the magnetic component includes a first magnetic core 13 and a second magnetic core 14, which can be separated from each other. In some embodiments, the first magnetic core 13 is an upper magnetic core and disposed on the first surface 111, and the second magnetic core 14 is a lower magnetic core and disposed on the second surface 112. The first magnetic core 13 and the second magnetic core 14 are buckled on the first circuit board 11 through the through hole 110. In the embodiment, the second circuit board 12 includes a third surface 121, a fourth surface 122, and a hollow opening 120. The third surface 121 faces the second surface 112. In the embodiment, the hollow opening 120 runs through the third surface 121 and the fourth surface 122. Moreover, the hollow opening 120 is disposed and spatially corresponding to the second magnetic core 14 of the magnetic component, and the second magnetic core 14 of the magnetic component is at least partially exposed via the hollow opening 120. In other words, in a projection plane parallel to the third surface, a projected area of the hollow opening is entirely within a projected area of the second magnetic core of the magnetic component. In some embodiments, the shape of the hollow opening 120 is circular, rectangular, square or oval.

In the embodiment, the auxiliary production clamp 2 is utilized and operated in a working state to clamp the first magnetic core 13 and the second magnetic core 14 of the power module 1. The auxiliary production clamp 2 includes a first clamp element 21, a second clamp element 22, a pivot shaft 23, an elastic component 24 and an ejector assembly 25. The first clamp element 21 includes a first pressing end 211, a first operating end 212 and a first pivoting portion 213. The first operating end 212 and the first pressing end 211 are opposite to each other. The first pivoting portion 213 is located between the first operating end 212 and the first pressing end 211. The second clamp element 22 includes a second pressing end 221, a second operating end 222, a second pivoting portion 223 and a through opening 220. The second operating end 222 and the second pressing end 221 are opposite to each other. The second pivoting portion 223 is located between the second operating end 222 and the second pressing end 221. The through opening 220 runs through the second pressing end 221, and the second pressing end 221 is spatially corresponding to the first pressing end 211. The pivot shaft 23 runs through the first pivoting portion 213 and the second pivoting portion 223, so that the pivot shaft 23 is pivotally connected between the first clamp element 21 and the second clamp element 22 to allow the first pressing end 211 and the second pressing end 221 to approach or separate from each other. In the embodiment, the auxiliary production clamp 2 further includes two circlips 231,232, which are arranged at two opposite ends of the pivot shaft 23. In some embodiments, the first pivoting portion 213 and the second pivoting portion 223 are located between the two circlips 231, 232, so that the first clamp element 21 and the second clamp element 22 are pivotally connected to each other. Certainly, the present disclosure is not limited thereto. In some embodiments, the elastic component 23 is a torsion spring, which is sleeved on an outer periphery of the pivot shaft 23 and abutted between the first clamp element 21 and the second clamp element 22 to provide a pressing force causing the first pressing end 211 and the second pressing end 221 close to each other. The ejector assembly 25 is provided on the second pressing end 221 and spatially corresponding to the through opening 220 and the hollow opening 120 of the second circuit board 12. When the auxiliary production clamp 2 is operated in the working state, the first pressing end 211 downwardly presses against the top surface of the first magnetic core 13, the second pressing end 221 upwardly presses against the fourth surface 122 of the second circuit board 12, and an abutting end 261 of the ejector assembly 25 is driven to run through the through opening 220 of the second clamp element 22 and the hollow opening 120 of the second circuit board 12 and push against the bottom surface of the second magnetic core 14. In this way, the auxiliary production clamp 2 can firmly clamp the power module 1 after the assembling work is completed. It ensures that the uniformity of the glue pre-placed between the first magnetic core 13 and the first circuit board 11 and the glue pre-placed between the first magnetic core 13 and the second magnetic core 14 are maintained. Moreover, before the glue is cured at a high temperature, the structural stability of the magnetic cores after being assembled is maintained, so as to facilitate the manufacture of the power module 1. In some embodiments, the first clamp element 21, the second clamp element 22, the pivot shaft 23, the elastic component 24 and the ejector assembly 25 are made of the same or different high-temperature-resistant metal materials to facilitate the power module 1 clamped by the auxiliary production clamp 2 to perform a high temperature treatment process. Certainly, the present disclosure is not limited thereto.

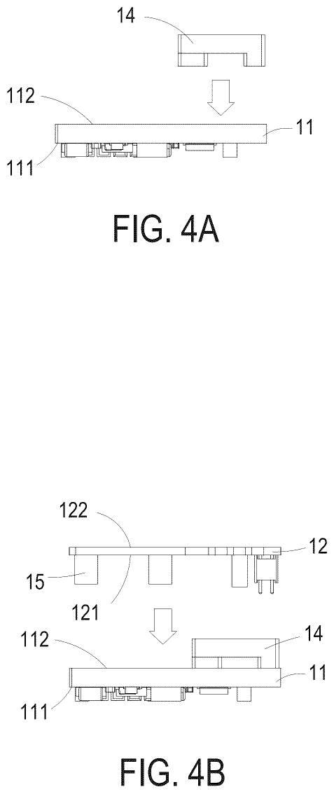

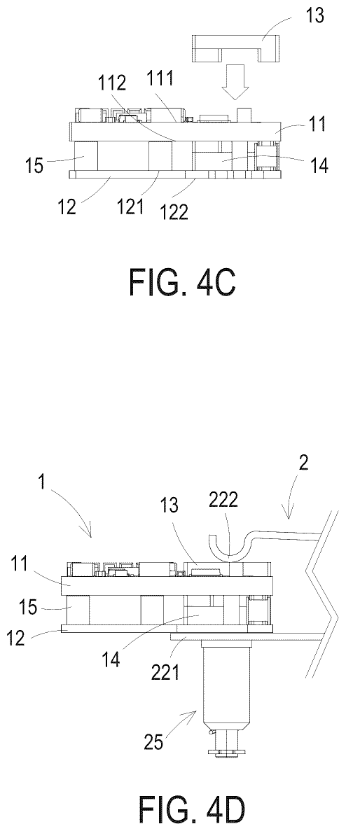

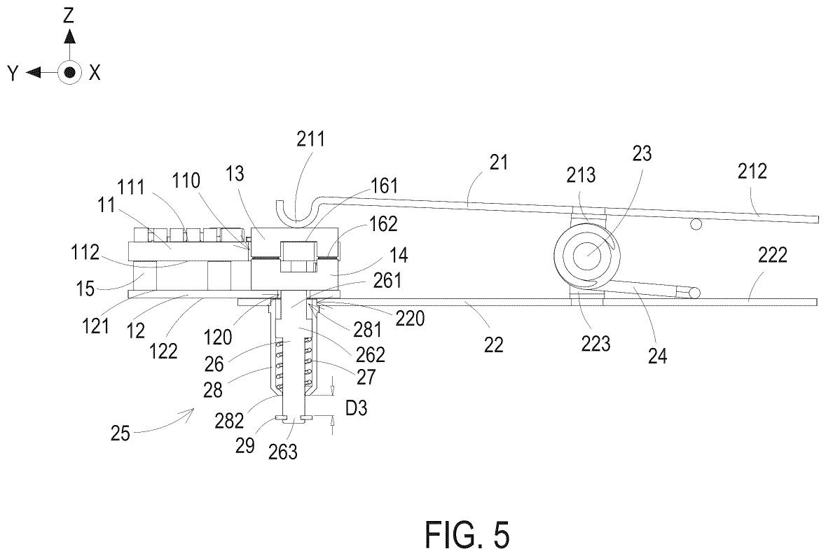

With respect to the auxiliary production clamp 2 applied to the power module 1, the present disclosure also provides a using method. FIGS. 4A to 4D are schematic diagrams illustrating a process of using the auxiliary production clamp to produce the power module according to an embodiment of the present disclosure. FIG. 5 is a cross-sectional view illustrating the auxiliary production clamp operated in a working state to clamp the power module according to the embodiment of the present disclosure. In the embodiment, before the auxiliary production clamp 2 clamps the power module 1, the main structures of the power module 1 such as the first circuit board 11, the second circuit board 12, the first magnetic core 13 and the second magnetic core 14 are assembled in advance. Firstly, as shown in FIG. 4A, the second surface 112 of the first circuit board 11 faces upward, and the second magnetic core 14 is aligned to the through hole 110 (refer to FIG. 2B) from top to bottom and placed on the second surface 112 of the first circuit board 11. At this time, the second magnetic core 14 and the first circuit board 11 are arranged in sequence from top to bottom, and the second magnetic core 14 is pre-placed on the second surface 112 of the first circuit board 11, so that second magnetic core 14 is allowed to be pre-bonded to the second surface 112 by gravity of the second magnetic core 14. Then, as shown in FIG. 4B, the third surface 121 of the second circuit board 12 faces downwardly toward the second surface 112 of the first circuit board 11, and is placed on the second magnetic core 14 and the first circuit board 11. In the embodiment, the first circuit board 11 is a power board, and the second circuit board 12 is a control board. When the second circuit board 12, the second magnetic core 14 and the first circuit board 11 are arranged in sequence from top to bottom, the first circuit board 11 and the second circuit board 12 are further electrically connected through at least one conductive connector 15 by welding. In some embodiments, the at least one conductive connector 15 is connected to the second surface 112 and the third surface 121 by a welding process. The conductive connector 15 and the second magnetic core 14 of the magnetic component are misaligned to each other in view of the stacking direction (i.e., the Z axial direction), and the second magnetic core 14 is pre-placed between the second circuit board 12 and the first circuit board 11, and positioned through the through hole 110 of the first circuit board 11. Afterwards, the pre-assembled structure of the second circuit board 12, the second magnetic core 14 and the first circuit board 11 is flipped horizontally. At this time, the second magnetic core 14 falls onto the third surface 121 of the second circuit board 12 under the action of its gravity. Then, a glue is dispensed on the second magnetic core 14 and the first circuit board 11. Finally, as shown in FIG. 4C, the first magnetic core 13 is aligned to the through hole 110 and placed on the first surface 111 of the first circuit board 11 with the second magnetic core 14, thereby completing the pre-assembled structure of the power module 1. In the embodiment, when the first magnetic core 13, the first circuit board 11, the second magnetic core 14 and the second circuit board 12 are arranged in sequence from top to bottom, and the first magnetic core 13 has to be attached to the first surface 111 using a glue 161 and attached to the second magnetic core 14 using a glue 162. Since the glue 161 and the glue 162 need to be cured by heating for a long time in a high temperature environment, the auxiliary production fixture 2 of the present disclosure can be utilized to press the magnetic component of the pre-assembled power module 1.

In the embodiment, the auxiliary production clamp 2 can be operated in a working state to clamp the first magnetic core 13 and the second magnetic core 14 of the power module 1. As mentioned above, the auxiliary production clamp (tool) 2 includes the first clamp element 21, the second clamp element 22, the pivot shaft 23, the elastic component 24 and the ejector assembly 25. The ejector assembly 25 further includes an ejector pin 26, a metal tube 28, an engagement component 29 and a compression spring 27. In the embodiment, the ejector pin 26 includes an abutting end 261, a clamped end 263 and a limiting portion 262. The abutting end 261 and the clamped end 263 are two opposite ends of each other. The limiting portion 262 is located between the abutting end 261 and the clamped end 263. A top opening 281 of the metal tube 28 is aligned with the through opening 210 of the second clamp element 22, and the metal tube 28 and first clamp element 21 are arranged on two opposite sides of the second clamp element 22, respectively. In the embodiment, the limiting portion 262 of the ejector pin 26 is accommodated in the metal tube 28. The clamped end 263 runs through a bottom 282 of the metal tube 28 to engage with the engagement component 29, and the compression spring 27 is accommodated in the metal tube 28 and arranged between the limiting portion 262 and the bottom 282 of the metal tube 28. In the embodiment, when an external pressure is acted on the ejector pin 26, the limiting portion 262 is slid along an interior of the metal tube 28 to compress the compression spring 27. On the other hand, when the external pressure is eliminated, an elastic force of the compression spring 27 pushes the limiting portion 262 to slide in an opposite direction along the metal tube 28 until the engagement component 29 abuts the bottom 282 of the metal tube 28.

Notably, in the working state, the first pressing end 211 of the auxiliary production clamp (tool) 2 presses against the top surface of the first magnetic core 13, the first magnetic core 13 presses against the first circuit board 11, the second pressing end 221 presses against the fourth surface 122 of the second circuit board 12, and the elastic force of the compression spring 27 pushes the limiting portion 262 to drive the abutting end 261, so that the abutting end 261 runs through the through opening 220 of the second clamp element 22 and the hollow opening 120 of the second circuit board and push against the bottom surface of the second magnetic cover 14.

In the embodiment, the first pressing end 211 includes a convex arc portion having an arc surface convexly arranged toward the second pressing end 221. In some embodiments, the convex arc portion is a U-shaped structure, as shown in FIG. 5. When the first pressing end 211 presses against the top surface of the first magnetic core 13 in the working state, the convex arc portion is tangent to the top surface of the first magnetic core 13. Therefore, when the auxiliary production clamp (tool) 2 clamps the power module 1, an effective pressing action of the first magnetic core 13 and the second magnetic core 14 in the power module 1 is completed simultaneously. The operation is simple and fast. Moreover, it ensures the uniformity of the glue 161 dispensed between the first magnetic core 13 and the first surface 111 of the first circuit board 11 and the uniformity of the glue 162 dispensed between the first magnetic core 13 and the second magnetic core 14. Before the glue 161 and 162 are cured at high temperature, the structural stability of the magnetic cores after being assembled is maintained. After the power module 1 and the auxiliary production clamp 2 are processed through the high-temperature furnace, the glue 162 between the bonding magnetic component and the glue 161 between the first magnetic core 13 and the first circuit board 11 are completely cured. Thereafter, the auxiliary production clamp 2 can be opened to easily remove the power module 1.

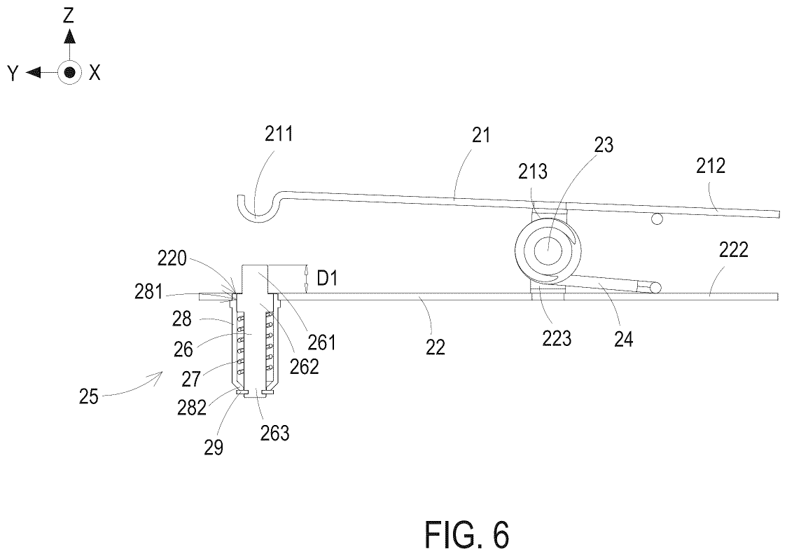

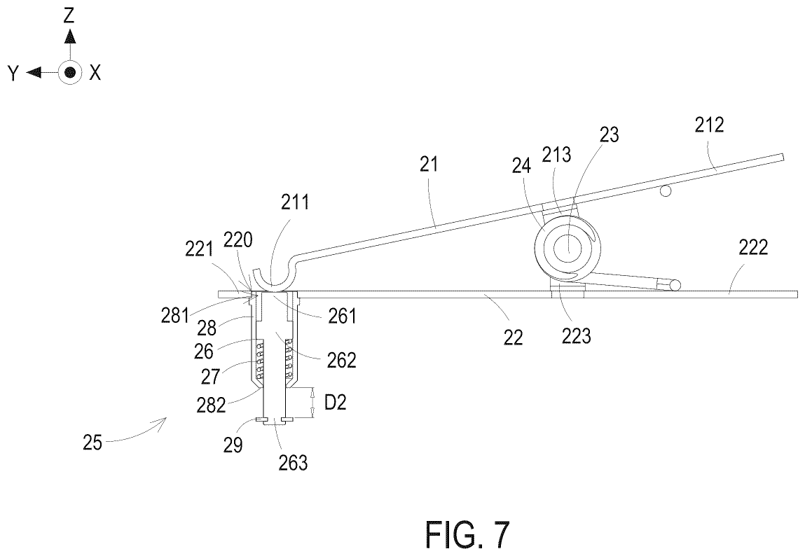

FIG. 6 is a cross-sectional view illustrating the auxiliary production clamp having the ejector assembly not affected by an external force according to the embodiment of the present disclosure. FIG. 7 is a cross-sectional view illustrating the auxiliary production clamp operated in an initial state according to the embodiment of the present disclosure. Please refer to FIG. 5 to FIG. 7. In the embodiment, when the auxiliary production clamp 2 and the ejector assembly 25 are not affected by an external force, the state is as shown in FIG. 6. The compression spring 27 pushes the ejector pin 26 through the limiting portion 262, so that the engagement component 29 contacts and pushes against the bottom 282 of the metal tube 28. At the same time, the abutting end 261 of the ejector pin 26 protrudes out of the top opening 281 and the through hole 220 to form a protruding length D1 relative to the second pressing end 221. In the embodiment, the pressing force provided by the elastic component 24 between the first pressing end 211 and the second pressing end 221 is greater than the elastic force of the compression spring 27. When the auxiliary production clamp 2 is operated in an initial state, the state is as shown in FIG. 7. The pressing force of the first clamp element 21 and the second clamp element 22 drives the first pressing end 211 to press against the ejector pin 26 and the compression spring 27, so that the abutting end 261 of the ejector pin 26 does not run through the through opening 220. That is, when the auxiliary production clamp 2 is operated in the initial state, the abutting end 261 is accommodated in the metal tube 28, the limiting portion 262 is close to the bottom 282 of the metal tube 28 to compress the compression spring 27, and the clamped end 263 and the engagement component 29 are slid and separated from the bottom 282 of the metal tube 28 to form a compressible distance D2. Since the first pressing end 211 further presses downwardly against the abutting end 261 with the convex arc portion of the U-shaped structure, the compressible distance D2 is greater than the protruding length D1. In the embodiment, when the auxiliary production clamp 2 is operated in the working state as shown in FIG. 5, the clamped end 263 and the engagement component 29 are slide and separated from the bottom 282 of the metal tube 28 to form a working distance D3, and the working distance D3 is smaller than the compressible distance D2 and greater than zero. Certainly, the actuation (action) process of the ejector assembly 25 is adjustable according to the practical requirements. The present disclosure is not limited thereto and not redundantly described hereafter.

In summary, the present disclosure provides an auxiliary production clamp for a power module and a using method thereof. After all components of a DC power module are assembled, it is necessary to ensure the uniformity of the glue between the upper magnetic core and the upper circuit board, and the glue between the upper magnetic core and the lower magnetic core. Moreover, before the glue is cured at high temperature, the structural stability of the magnetic cores after being assembled is also important. The present disclosure provides an ejector assembly assembled by utilizing high-temperature-resistant metal clips. In a working state, the effective pressing action of the upper magnetic core and the lower magnetic core in the power module can be completed simultaneously, and the operation is simple and fast. After the power module and the auxiliary production clamp are processed through the high-temperature furnace, the glue between the two magnetic cores and the glue between the upper magnetic core and the upper circuit board are completely cured, and then the auxiliary production clamp can be opened to remove the power module easily. The main structure of the power module includes an upper circuit board, a lower circuit board, an upper magnetic core and a lower magnetic core. The lower magnetic core is disposed between the upper circuit board and the lower circuit board, and the upper magnetic core is disposed on the first surface of the upper circuit board. During the assembling and manufacturing of the magnetic component, the lower magnetic core is pre-placed on the second surface of the upper circuit board, and is attached to the second surface of the upper circuit board by the lower magnetic core's own gravity. Then, the third surface of the lower circuit board is placed horizontally to face downward on the second surface of the upper circuit board. After welding, the upper circuit board and the lower circuit board are connected together. Next, the power module is flipped horizontally so that the fourth surface of the lower circuit board faces downward. At this time, the lower magnetic core falls to the third surface under the action of its own gravity. After the glue is dispensed on the corresponding positions of the lower magnetic core and the upper circuit board, the upper magnetic core is further placed on the upper circuit board. In this way, the auxiliary production clamp is utilized to clamp the power module after being assembled. It ensures the uniformity of the glue between the upper magnetic core and the upper circuit board, and the glue between the upper magnetic core and the lower magnetic core. Furthermore, before the glue is cured at a high temperature, the structural stability of the magnetic cores after being assembled is maintained. When the assembled power module is clamped by the auxiliary production clamp, the ejector pin of the ejector assembly runs through the opening of the lower circuit board, and the pressing force of the upper clamp element on the upper magnetic core and the lower clamp element on the second circuit board is greater than the lifting force of the ejector assembly on the lower magnetic core, and the power module is clamped between the upper clamp element and the lower clamp element, while the structural stability of the magnetic component is maintained. After the power module and the auxiliary production clamp are processed through the high-temperature furnace, the glue is evenly cured to bond the magnetic component, and bond the upper magnetic core and the upper circuit board. Thereafter, the auxiliary production clamp can be removed easily to complete the manufacture of the power module.

It is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An auxiliary production clamp for a power module, comprising:
a first clamp element, comprising a first pressing end;
a second clamp element, comprising a second pressing end and a through opening, wherein the through opening runs through the second pressing end, and the second pressing end is spatially corresponding to the first pressing end;
a pivot shaft pivotally connected between the first clamp element and the second clamp element to allow the first pressing end and the second pressing end to approach or separate from each other;
an elastic component sleeved on an outer periphery of the pivot shaft and abutted between the first clamp element and the second clamp element to provide a pressing force causing the first pressing end and the second pressing end close to each other; and
an ejector assembly provided on the second pressing end and comprising an ejector pin, a metal tube, an engagement component and a compression spring, wherein the ejector pin comprises an abutting end, a clamped end and a limiting portion, the abutting end and the clamped end are two opposite ends of each other, the limiting portion is located between the abutting end and the clamped end, a top opening of the metal tube is aligned with the through opening of the second clamp element, and the metal tube and first clamp element are arranged on two opposite sides of the second clamp element, respectively, wherein the limiting portion of the ejector pin is accommodated in the metal tube, the clamped end runs through a bottom of the metal tube to engage with the engagement component, and the compression spring is accommodated in the metal tube and arranged between the limiting portion and the bottom of the metal tube, wherein when an external pressure is acted on the ejector pin, the limiting portion is slid along an interior of the metal tube to compress the compression spring, wherein when the external pressure is eliminated, an elastic force of the compression spring pushes the limiting portion to slide in an opposite direction along the metal tube until the engagement component abuts the bottom of the metal tube.

2. The auxiliary production clamp according to claim 1, wherein the power module comprises:
a first circuit board, comprising a first surface, a second surface and a through hole, wherein the through hole runs through the first surface and the second surface;
a magnetic component, comprising a first magnetic core and a second magnetic core, wherein the first magnetic core and the second magnetic core are disposed on the first surface and the second surface, respectively, and buckled on the first circuit board through the through hole; and
a second circuit board, comprising a third surface, a fourth surface, and a hollow opening, wherein the third surface faces the second surface, the hollow opening runs through the third surface and the fourth surface and is disposed and spatially corresponding to the second magnetic core of the magnetic component, and the second magnetic core of the magnetic component is at least partially exposed via the hollow opening;
wherein when the auxiliary production clamp is operated in a working state, the first pressing end presses against the first magnetic core, the second pressing end presses against the second circuit board, and the elastic force of the compression spring pushes against the limiting portion, so that the abutting end of the ejector pin is driven to run through the through opening of the second clamp element and the hollow opening of the second circuit board and push against the second magnetic core.

3. The auxiliary production clamp according to claim 2, wherein the first pressing end comprises a convex arc portion having an arc surface convexly arranged toward the second pressing end, wherein when the first pressing end presses against the first magnetic core in the working state, the convex arc portion is tangent to a surface of the first magnetic core.

4. The auxiliary production clamp according to claim 3, wherein the convex arc portion is a U-shaped structure.

5. The auxiliary production clamp according to claim 2, wherein the first circuit board is a power board, the second circuit board is a control board, the first circuit board and the second circuit board are electrically connected through a conductive connector welded therebetween, wherein the conductive connector and the magnetic components are misaligned to each other.

6. The auxiliary production clamp according to claim 2, wherein the magnetic component has a center position corresponding to the hollow opening of the second circuit board.

7. The auxiliary production clamp according to claim 2, wherein the first magnetic core is bonded to the second magnetic core and the first surface using a glue.

8. The auxiliary production clamp according to claim 1, wherein when the auxiliary production clamp is operated in an initial state, the pressing force of the first clamp element and the second clamp element drives the first pressing end to press against the ejector pin and the compression spring, so that the ejector pin does not run through the through opening.

9. The auxiliary production clamp according to claim 1, wherein when the compression spring pushes against the ejector pin through the limiting portion, the engagement component contacts and abuts against the bottom of the metal tube, and the abutting end protrudes out of the through opening to form a protruding length.

10. The auxiliary production clamp according to claim 9, wherein when the auxiliary production clamp is operated in an initial state, the abutting end is accommodated in the metal tube, the limiting portion is close to the bottom of the metal tube to compress the compression spring, and the clamped end and the engagement component are slid and separated from the bottom of the metal tube to form a compressible distance, wherein the compressible distance is greater than the protruding length.

11. The auxiliary production clamp according to claim 10, wherein when the auxiliary production clamp is operated in a working state, the clamped end and the engagement component are slide and separated from the bottom of the metal tube to form a working distance, and the working distance is smaller than the compressible distance.

12. The auxiliary production clamp according to claim 1, wherein the pressing force is greater than the elastic force of the compression spring.

13. The auxiliary production clamp according to claim 1, wherein the first clamp element and the second clamp element are made of a high-temperature-resistant metal material.

14. The auxiliary production clamp according to claim 1, wherein the first clamp element further comprises a first operating end and a first pivoting portion, the first operating end and the first pressing end are opposite to each other, and the first pivoting portion is located between the first operating end and the first pressing end, wherein the second clamp element further comprises a second operating end and a second pivoting portion, the second operating end and the second pressing end are opposite to each other, and the second pivoting portion is located between the second operating end and the second pressing end, wherein the pivoting shaft runs through the first pivoting portion, the second pivoting portion and the elastic component, and the elastic component has two ends connected to the first operating end and the second operating end to push against the first operating end and the second operating end, respectively, so that the pressing force is provided between the first pressing end and the second pressing end.

15. The auxiliary production clamp according to claim 14, further comprising two circlips arranged at two opposite ends of the pivot shaft, wherein the first pivoting portion and the second pivoting portion are located between the two circlips.

16. A using method of an auxiliary production clamp for a power module, comprising a step of:
providing the auxiliary production clamp, wherein the auxiliary production clamp is operated in a working state to clamp a first magnetic core, a first circuit board, a second magnetic core and a second circuit board of the power module, wherein the first circuit board comprises a first surface, a second surface and a through hole, and the through hole runs through the first surface and the second surface, wherein the first magnetic core and the second magnetic core are disposed on the first surface and the second surface, respectively, and buckled on the first circuit board through the through hole, wherein the second circuit board comprises a third surface, a fourth surface, and a hollow opening, the third surface faces the second surface, the hollow opening runs through the third surface and the fourth surface and is disposed and spatially corresponding to the second magnetic core, and the second magnetic core is at least partially exposed via the hollow opening, wherein the auxiliary production clamp comprises:
a first clamp element, comprising a first pressing end;
a second clamp element, comprising a second pressing end and a through opening, wherein the through opening runs through the second pressing end, and the second pressing end is spatially corresponding to the first pressing end;
a pivot shaft pivotally connected between the first clamp element and the second clamp element to allow the first pressing end and the second pressing end to approach or separate from each other;
an elastic component sleeved on an outer periphery of the pivot shaft and abutted between the first clamp element and the second clamp element to provide a pressing force causing the first pressing end and the second pressing end close to each other; and
an ejector assembly provided on the second pressing end and spatially corresponding to the through opening and the hollow opening, wherein when the auxiliary production clamp is operated in the working state, the first pressing end presses against the first magnetic core, the second pressing end presses against the second circuit board, and the pressing force of the elastic component pushes against the ejector assembly, so that an abutting end of the ejector assembly is driven to run through the through opening of the second clamp element and the hollow opening of the second circuit board and push against the second magnetic core.

17. The using method according to claim 16, wherein the ejector assembly comprises an ejector pin, a metal tube, an engagement component and a compression spring, wherein the ejector pin comprises the abutting end, a clamped end and a limiting portion, the abutting end and the clamped end are two opposite ends of each other, the limiting portion is located between the abutting end and the clamped end, a top opening of the metal tube is aligned with the through opening of the second clamp element, and the metal tube and first clamp element are arranged on two opposite sides of the second clamp element, respectively, wherein the limiting portion of the ejector pin is accommodated in the metal tube, the clamped end runs through a bottom of the metal tube to engage with the engagement component, and the compression spring is accommodated in the metal tube and arranged between the limiting portion and the bottom of the metal tube, wherein when an external pressure is acted on the ejector pin, the limiting portion is slid along an interior of the metal tube to compress the compression spring, wherein when the external pressure is eliminated, an elastic force of the compression spring pushes the limiting portion to slide in an opposite direction along the metal tube until the engagement component abuts the bottom of the metal tube.

18. The using method according to claim 17, wherein the pressing force is greater than the elastic force of the compression spring.

19. The using method according to claim 16, wherein the second magnetic core and the first circuit board are arranged in sequence from top to bottom, and the second magnetic core is pre-placed on the second surface of the first circuit board, so that second magnetic core is allowed to be pre-bonded to the second surface by gravity of the second magnetic core.

20. The using method according to claim 19, wherein the second circuit board, the second magnetic core and the first circuit board are arranged in sequence from top to bottom, and at least one conductive connector is connected to the second surface and the third surface by a welding process.

21. The using method according to claim 20, wherein the first magnetic core, the first circuit board, the second magnetic core and the second circuit board are arranged in sequence from top to bottom, and the first magnetic core is attached to the second magnetic core and the first surface by a glue.

22. The using method according to claim 16, wherein the first circuit board is a power board, the second circuit board is a control board, the first circuit board and the second circuit board are electrically connected through at least one conductive connector welded therebetween, wherein the at least one conductive connector and the second magnetic core are misaligned to each other.

23. The using method according to claim 16, wherein the second magnetic core has a center position corresponding to the hollow opening of the second circuit board.

24. The using method according to claim 16, wherein the first magnetic core is bonded to the second magnetic core and the first surface using a glue.

25. The using method according to claim 24, wherein the glue is produced for a high temperature curing time, and the auxiliary production clamp presses the first magnetic core and the second magnetic core together within the high temperature curing time.

26. The using method according to claim 16, wherein the first clamp element, the second clamp element, the elastic component and the ejector assembly are made of a high-temperature-resistant metal material.
